(19) United States
(12) Patent Application Publication
(10) Pub. No.: US 2018/0054214 A1
(43) Pub. Date: Feb. 22, 2018

(54) COMMUNICATION METHOD AND COMMUNICATION SYSTEM

(71) Applicant: FUJITSU LIMITED, Kawasaki-shi (JP)

(72) Inventor: Noriaki TAKAHASHI, Sendai (JP)

(73) Assignee: FUJITSU LIMITED, Kawasaki-shi (JP)

(21) Appl. No.: 15/648,178

(22) Filed: Jul. 12, 2017

(30) Foreign Application Priority Data
Aug. 16, 2016 (JP) 2016-159553

(51) Int. Cl. H03M 5/14; H04L 27/26; H04W 88/08; H04L 5/00; H04B 17/21; H04L 12/26; H03M 7/20

(52) U.S. Cl. CPC H03M 5/14; H04L 27/2627; H04W 88/085; H03M 7/20; H04L 5/0035; H04B 17/21; H04L 43/50; H04L 27/2601

(57) ABSTRACT

A communication method executed by a communication system including a transmission circuit and a reception circuit, the communication method includes encoding, by the transmission circuit, inputted data according to an encoding method of converting a pre-converted bit string into a bit string in which a number of consecutive bits representing a same value is equal to or less than a predetermined threshold value, transmitting a first serial signal representing the encoded data, in a first period in which a radio signal outputted from the transmission circuit is communicated wirelessly, and transmitting a second serial signal representing a bit string which includes a continuous number of consecutive bits representing a same value, in a second period in which the radio signal is not communicated wirelessly, the continuous number being greater than the threshold value, and receiving, by the reception circuit, the first serial signal and the second serial signal.

### CROSS-REFERENCE TO RELATED APPLICATION

This application is based upon and claims the benefit of priority of the prior Japanese Patent Application No. 2016-159553, filed on Aug. 16, 2016, the entire contents of which are incorporated herein by reference.

### FIELD

The embodiments discussed herein are related to a communication method and a communication system.

### BACKGROUND

Known is a communication system including: a transmission circuit configured to receive data on a radio signal, and to transmit a serial signal representing the received data; and a reception circuit configured to receive the serial signal (see Japanese Laid-open Patent Publications Nos. 2014-11551, 8-116286, and 2011-188356, for example). The communication system is applied to communications between a baseband unit (BBU) and a remote radio head (RRH) which are included in a radio base station, for example.

The transmission circuit encodes the received data according to an encoding method of converting an arbitrary bit string into a bit string in which the number of consecutive bits representing the same value is equal to or less than a threshold value. The encoding method is an 86/10B encoding method, for example. The transmission circuit transmits a serial signal representing the encoded data.

Meanwhile, as frequency at which values in the bit string represented by the serial signal change (in other words, toggle frequency) becomes higher, the amount of electric power consumed by the transmission circuit and the reception circuit (for example, electric power consumed due to their switching operation) (in other words, power consumption) becomes larger.

There is a case where in a period in which no radio signal is communicated wirelessly (in other words, in a non-communication period), the transmission circuit encodes a predetermined bit string (for example, a bit string including 0s in succession) according to the above-mentioned encoding method, and transmits a serial signal representing the encoded bit string. In this case, in the non-communication period, too, the number of consecutive bits representing the same value in the bit string represented by the serial signal is equal to or less than the above-mentioned threshold value. For this reason, the toggle frequency tends to become higher in the non-communication period as well. Accordingly, the amount of power consumption in the transmission circuit and the reception circuit tends to become larger.

Meanwhile, there is an idea that the communication by the communication system is halted in the non-communication period. The halted communication, however, involves a risk of putting the transmission circuit and the reception circuit out of synchronization. With the above problem taken into consideration, it is desirable that the power consumption in the transmission circuit and the reception circuit be reduced.

### SUMMARY

According to an aspect of the invention, a communication method executed by a communication system including a transmission circuit and a reception circuit, the communication method includes encoding, by the transmission circuit, inputted data according to an encoding method of converting a pre-converted bit string into a bit string in which a number of consecutive bits representing a same value is equal to or less than a predetermined threshold value, transmitting a first serial signal representing the encoded data, in a first period in which a radio signal outputted from the transmission circuit is communicated wirelessly, and transmitting a second serial signal representing a bit string which includes a continuous number of consecutive bits representing a same value, in a second period in which the radio signal is not communicated wirelessly, the continuous number being greater than the threshold value, and receiving, by the reception circuit, the first serial signal and the second serial signal.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a block diagram illustrating an example of a configuration of a base station apparatus in a first embodiment;

FIG. 2 is a block diagram illustrating an example of a configuration of a BBU and an RRH in FIG. 1;

FIG. 3 is a block diagram illustrating an example of a configuration of an IF/circuit in the BBU and an I/F circuit in the RRH in FIG. 2;

FIG. 4 is a block diagram illustrating an example of a configuration of a transmission frame processing unit and a serializer in FIG. 3;

FIG. 5 is an explanatory diagram illustrating examples of a period in a radio frame in which a downlink communication is performed, and examples of a period in the radio frame in which an uplink communication is performed;

FIG. 6 is a table illustrating examples of a relationship between a pre-converted bit string and a post-converted bit string which is established in an encoding method;

FIGS. 7A, 7B, and 7C are explanatory diagrams respectively illustrating examples of a signal which is generated by the I/F circuit in FIG. 3 in a period in which no radio signal is communicated wirelessly;

FIG. 8 is a block diagram illustrating examples of configurations of a reception frame processing unit and a deserializer unit in FIG. 3;

FIGS. 9A, 9B, 9C, and 9D are explanatory diagrams respectively illustrating examples of a signal which is generated by an I/F circuit of a comparative example in a period in which no radio signal is communicated wirelessly; and

FIG. 10 is a block diagram illustrating an example of a configuration of a reception frame processing unit and a deserializer of the second embodiment.

### DESCRIPTION OF EMBODIMENTS

Hereinafter, referring to the accompanying drawings, descriptions are provided for embodiments. The below-discussed embodiments are provided as examples. Various modifications and techniques may be applied to the embodiments, even if they are not explicitly discussed below. In the drawings used for the embodiments, components denoted by the same reference signs are the same or similar to each other, unless modification or changes are indicated.

### First Embodiment

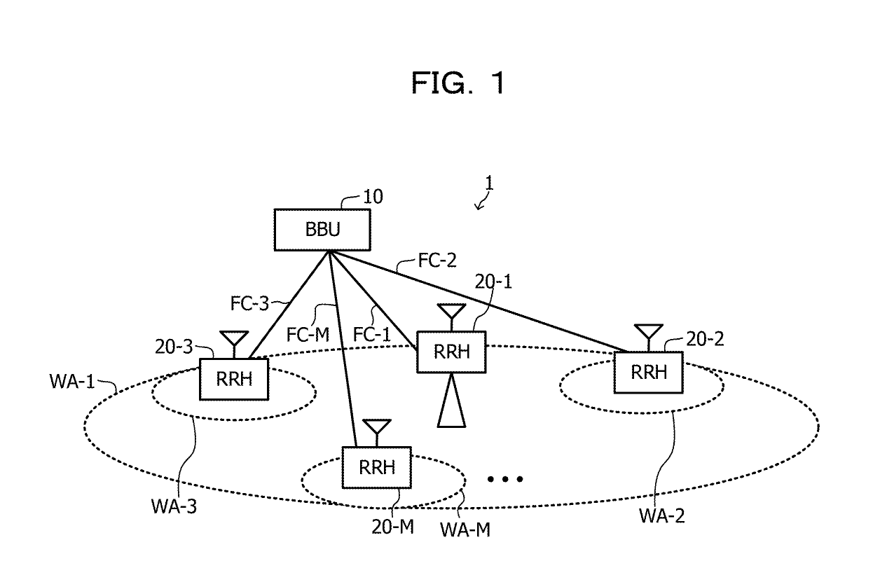

As illustrated in FIG. 1, a base station apparatus 1 of the first embodiment includes a BBU 10, and M RRH 20-1, 20-2, 20-3, . . . , 20-M. BBU stands for baseband unit. RRH stands for remote radio head. The value M is an integer equal to 1 (one) or larger. A RRH20-m is also referred to a RRH 20 as well, when a RRH does not have to be distinguished from each other. The value m is an integer from 1 to M.

The base station apparatus 1 makes wireless communications with a terminal device (for example, a user terminal) not illustrated in FIG. 1, according to a predetermined wireless communication method. In this example, the wireless communication method is LTE-Advanced. LTE stands for Long Term Evolution. The wireless communication method may be a method (for example, W-CDMA) different from LTE. W-CDMA stands for Wideband Code Division Multiple Access.

The base station apparatus 1 may be referred to as an evolved node B (eNB) or an access point. The BBU 10 may be referred to as a REC, a wireless controller, or a wireless control unit. REC stands for Radio Equipment Control or Radio Equipment Controller. The RRH 20 may be referred to as a wireless device, or a wireless unit. RE stands for Radio Equipment.

The RRH20-m forms a cell WA-m. The cell WA-m is an example of a wireless area. The cell WA-m may be referred to as a coverage area, or a communication area. For example, the cell WA-m is a macrocell, a microcell, a nanocell, a picocell, a femtocell, a homecell, a smallcell, a sector cell or the like. The RRH20-m makes wireless communications with terminal devices located within the cell WA-m which is formed by the RRH20-m.

In this example, the cell WA-1 is a macrocell, while the cells WA-2, . . . , WA-M are smallcells. In this example, at least some of the smallcells WA-2, . . . , WA-M are located within the macrocell WA-1. All the smallcells WA-2, . . . , WA-M may be located outside the macrocell WA-1.

In this example, in the macrocell WA-1, a radio signal is communicated according to the frequency division duplex (FDD) method. In this example, in each of the smallcells WA-2, . . . , WA-M, the radio signal is communicated according to the time division duplex (TDD) method. For example, the format of a radio frame to be used for wireless communications according to the TDD method is specified in 3GPP TS36.213.

The RRH 20-m is communicably connected to the BBU 10 via a communication cable FC-m. In this example, the communication cable FC-m includes an optical fiber. In this example, the BBU 10 and the RRH 20-m communicate with each other according to a predetermined communication standard. In this example, the communication standard is CPRI. CPRI stands for Common Public Radio Interface. The communication standard may be ORI. ORI stands for Open Radio Equipment Interface.

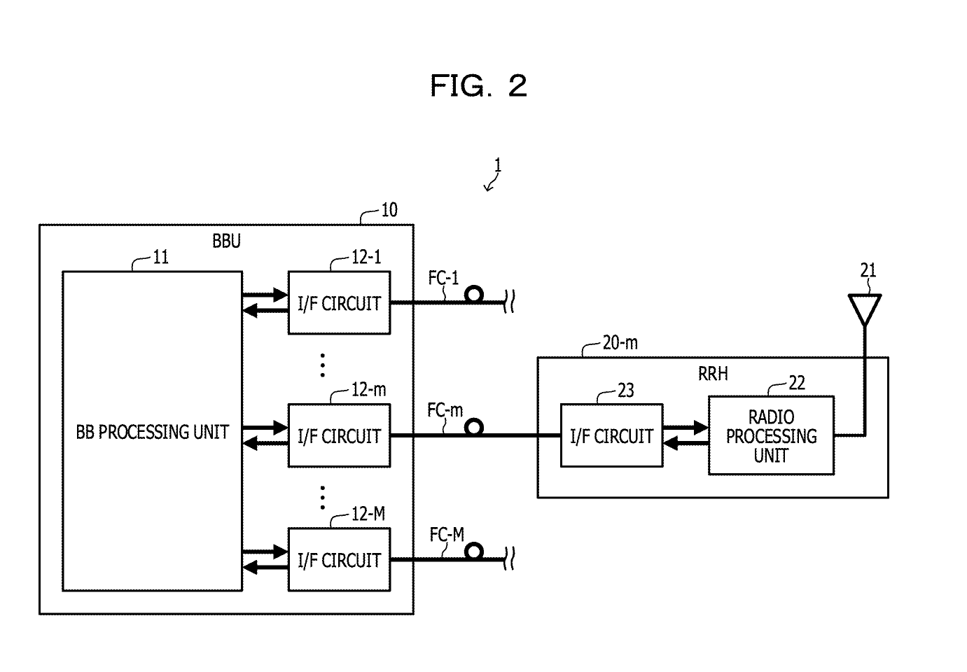

As illustrated in FIG. 2, for example, the BBU 10 includes a BB processing unit 11, and M I/F circuits 12-1, . . . , 12-m, . . . , 12-M. BB stands for Baseband. I/F stands for Interface.

The BB processing unit 11 generates radio information and IQ data for each of the M I/F circuits 12-1, . . . , 12-m, . . . , 12-M. In this example, radio information for the I/F circuit 12-m is information to be used to control wireless communications in the cell WA-m formed by the RRH 20-m. In this example, the radio information includes first radio information, second radio information, third radio information and fourth radio information.

The first radio information is information on whether to make the wireless communications according to the time division duplex (TDD) method. The second radio information is information on a period timing for the radio signal communication in the radio frame (for example, a timing of the beginning of the radio frame, or a time length from the beginning of the radio frame through a timing of the radio signal communication, or the like).

The radio frame is used for the radio signal communication. In this example, each radio frame is an element in a radio signal, and has a predetermined time length (in this example, 10 ms). In other words, each radio signal is formed from multiple radio frames in succession in the time axis.

The third radio information is information on a period timing for an uplink communication in the radio frame. The fourth radio information is information on a period timing for a downlink communication in the radio frame.

In this example, the uplink communication is a communication from a terminal device to the base station apparatus 1, while the downlink communication is a communication from the base station apparatus 1 to the terminal device.

The IQ data is data on the radio signal. In the example, the IQ data is on the amplitude and phase of the radio signal. For example, the BB processing unit 11 generates the IQ data based on information received from an external apparatus of the base station apparatus 1 (for example, another base station apparatus, an exchange apparatus or the like connected to the base station apparatus 1 via a communication network).

The BB processing unit 11 outputs the radio information and IQ data thus generated for the I/F circuit 12-m to the I/F circuit 12-m.

The I/F circuit 12-m generates control information. The control information is information to be used to maintain the connection between the BBU 10 and the RRH 20-m, as well as to control communications between the BBU 10 and the RRH 20-m. The control information may be referred to a control word. In this example, the control information is used to synchronize a communication frame, which is discussed later, between the BBN 10 and the RRH 20-m.

Based on the radio information received from the BB processing unit 11, the I/F circuit 12-m converts an electrical signal representing the IQ data received from the BB processing unit 11 and the generated control information into an optical signal representing them. Thereafter, the I/F circuit 12-m transmits the thus-converted optical signal to the RRH 20-m via the communication cable FC-m.

Via the communication cable FC-m, the I/F circuit 12-m receives an optical signal transmitted from the RRH 20-m.

Based on the radio information received from the BB processing unit 11, the I/F circuit 12-m converts the received optical signal into an electrical signal. Thereafter, the I/F circuit 12-m outputs the IQ data represented by the post-converted electrical signal to the BB processing unit 11.

The BB processing unit 11 processes the IQ data received from the I/F circuit 12-m. For example, based on the IQ data, the BB processing unit 11 generates information. Thereafter, the BB processing unit 11 transmits the generated information to the external apparatus of the base station apparatus 1 (for example, the other base station apparatus, the exchange apparatus or the like connected to the base station apparatus 1 via a communication network).

The RRH 20-m includes an antenna 21, a radio processing unit 22, and an I/F circuit 23.

The radio processing unit 22 generates radio information, and outputs the generated radio information to the I/F circuit 23. For example, the radio processing unit 22 may generate the radio information based on information received from the I/F circuit 23.

The radio processing unit 22 receives radio information via the antenna 21. The radio processing unit 22 generates IQ data which is represented by the received radio information. Thereafter, the radio processing unit 22 outputs the generated IQ data to the I/F circuit 23.

The I/F circuit 23 generates control information. Based on the radio information received from the radio processing unit 22, the I/F circuit 23 converts an electrical signal representing the IQ data received from the radio processing unit 22 and the generated control information into an optical signal representing them. Thereafter, the I/F circuit 23 transmits the post-converted optical signal to the BBU 10 via the communication cable FC-m.

Via the communication cable FC-m, the I/F circuit 23 receives an optical signal transmitted from the BBU 10. Based on the radio information received from the radio processing unit 22, the I/F circuit 23 converts the received optical signal into an electrical signal. Thereafter, the I/F circuit 23 outputs the IQ data represented by the post-converted electrical signal to the radio processing unit 22.

Via the antenna 21, the radio processing unit 22 receives the radio information which is represented by the IQ data received from the I/F circuit 23.

In this example, the optical signal from the I/F circuit 12-m to the I/F circuit 23, and the optical signal from the I/F circuit 23 to the I/F circuit 12-m are wavelength-multiplexed and transmitted.

Descriptions are hereinbelow provided for the I/F circuit 12-m and the I/F circuit 23.

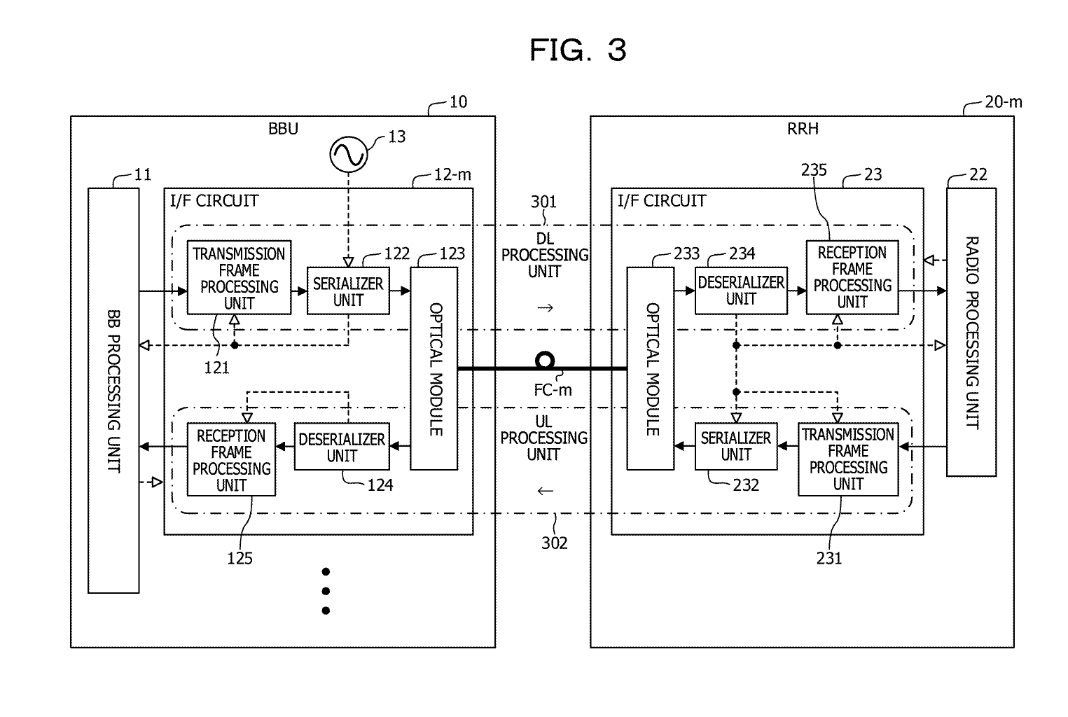

For example, as illustrated in FIG. 3, the I/F circuit 12-m includes a transmission frame processing unit 121, a serializer unit 122, an optical module 123, a deserializer unit 124, and a reception frame processing unit 125. The serializer unit 122 and the deserializer unit 124 may be referred to as a SerDes circuit. SerDes stands for Serializer/Deserializer.

The BBN 10 includes an oscillator 13.

For example, as illustrated in FIG. 3, the I/F circuit 23 includes a transmission frame processing unit 231, a serializer unit 232, an optical module 233, a deserializer unit 234, and a reception frame processing unit 235. The serializer unit 232 and the deserializer unit 234 may be referred to as a SerDes circuit.

In this example, the transmission frame processing unit 121, the serializer unit 122, the deserializer unit 234, and the reception frame processing unit 235 form a DL processing unit 301 configured to process downlink signals. In this example, the transmission frame processing unit 231, the serializer unit 232, the deserializer unit 124, and the reception frame processing unit 125 jointly form a UL processing unit 302 configured to process uplink signals. DL stands for Downlink. UL stands for Uplink.

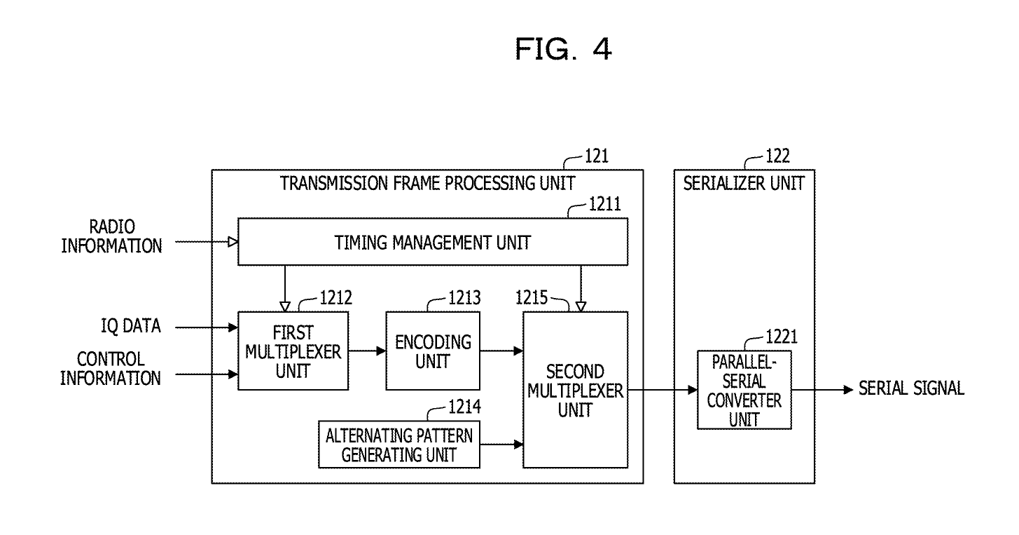

For example, as illustrated in FIG. 4, the transmission frame processing unit 121 includes a timing management unit 1211, a first multiplexer unit 1212, an encoding unit 1213, an alternating pattern generating unit 1214, and a second multiplexer unit 1215. The serializer unit 122 includes a parallel-serial converter unit 1221.

The first multiplexer unit 1212 multiplexes the IQ data received from the BB processing unit 11 and the control information generated by the I/F circuit 23 to generate a communication frame according to the communication standard. The first multiplexer unit 1212 outputs a parallel signal representing the generated communication frame to the encoding unit 1213.

In this example, the communication frame includes: a header section forming a starting section of the communication frame; and a payload section following the header section. The header section stores the control information. The payload section stores the IQ data.

The communication frame may be referred to as a CPRI frame, or a Basic Frame. For example, the header section is 128 (=4×32) bits long. Meanwhile, the payload section is 1920 (=60×32) bits long. The bit count of the header section may be at a value which is different from 128. The bit count of the payload section may be at a value which is different from 1920.

Based on the radio information received from the BB processing unit 11, the timing management unit 1211 controls the multiplexing of the control information and the IQ data by the first multiplexer unit 1212. In other words, based on the radio information received from the BB processing unit 11, the timing management unit 1211 controls timings at which the control information and the IQ data are outputted from the first multiplexer unit 1212.

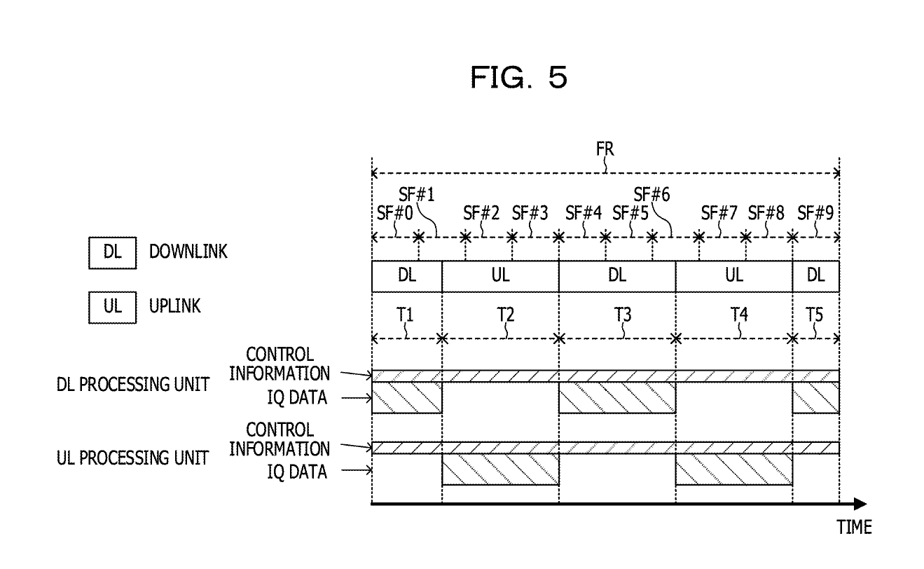

For example, as illustrated in FIG. 5, a radio frame FR includes 10 sub-frames SF#0 to SF#9. In the TTD method, downlink communications are performed in some periods in the radio frame FR, and uplink communications are performed in the other periods (in other words, the rest) in the radio frame FR. In an example illustrated in FIG. 5, downlink communications are performed in periods T1, T3, T5, and uplink communications are performed in periods T2, T4.

Thus, the DL processing unit 301 transmits a communication frame with the control information and the IQ data respectively stored in the header section and the payload section in the periods (in other words, the DL communication periods) T1, T3, T5 in which the downlink communications are being performed. Meanwhile, the DL processing unit 301 transmits a communication frame with the control information stored in the header section, and with no IQ data stored in the payload section, in the periods (in other words, the DL non-communication periods) T2, T4 in which no downlink communications are performed.

In this example, the DL communication periods T1, T3, T5 for the DL processing unit 301 are instances of a first period in which radio signals are communicated wirelessly. In this example, the DL non-communication periods T2, T4 for the DL processing unit 301 are instances of a second period in which no radio signal is communicated wirelessly.

The encoding unit 1213 encodes the parallel signal received from the first multiplexer unit 1212 according to a predetermined encoding method. The encoding method is a method for converting an arbitrary bit string into a bit string which includes consecutive bits representing the same value where the number of such bits is equal to or less than a predetermined threshold value.

In this example, in the encoding method, relationships between pre-converted bit strings and post-converted bit strings are established in advance, and each bit string is converted based on the relationships. In this example, the bit count of each pre-converted bit string and the bit count of the corresponding post-converted bit string are determined in advance.

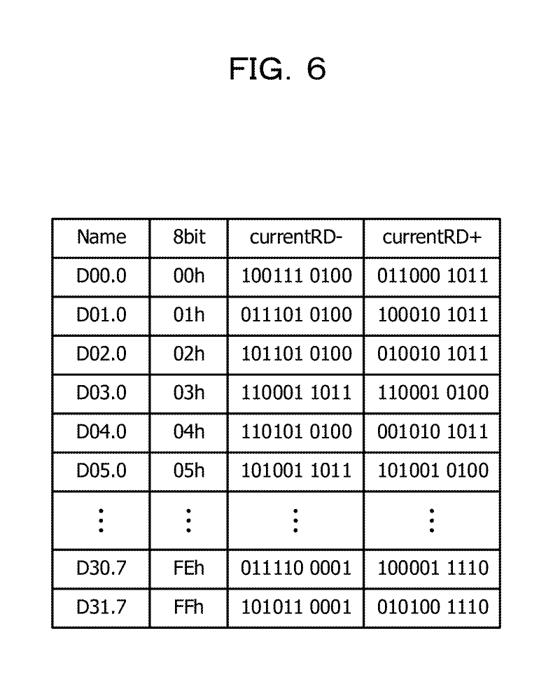

In this example, the encoding method is an 8B/10B encoding method. For example, in the 86/10B method, the threshold value is 4. For example, as illustrated in FIG. 6, relationships between pre-converted bit strings and post-converted bit strings are established in advance. A column “Name” represents names or labels. A column “8 bit” represents pre-converted bit strings. A column “currentRD−” and a column “currentRD+” represent post-converted bit strings. RD stands for Running Disparity.

An object bit string is converted such that when a “currentRD+” bit string is used as a bit string immediate before the object bit string, a corresponding “currentRD−” bit string is used as the post-converted bit string obtained by converting the object bit string. Otherwise, an object bit string is converted such that when a “currentRD−” bit string is used as a bit string immediate before the object bit string, a corresponding “currentRD+” bit string is used as the post-converted bit string obtained by converting the object bit string.

A bit string to be encoded according to the encoding method (in other words, a pre-converted object bit string), or a bit string obtained according to the encoding method (in other words, a post-converted object bit string) may be referred to as a “word”.

The encoding unit 1213 outputs the post-encoded parallel signal to the second multiplexer unit 1215.

The alternating pattern generating unit 1214 generates an alternating pattern signal. The alternating pattern signal represents a bit string which includes consecutive bits representing the same value where the number of such bits is a continuous number greater than the above-mentioned threshold value. In this example, the alternating pattern signal represents a bit string including an alternating series of a first bit string with the continuous number of 0s in succession and a second bit string with the continuous number of 1s in succession.

In this example, the continuous number is less than an upper limit number to be allowed for the I/F circuit 23 to be synchronized with the I/F circuit 12-m based in the received serial signal (in other words, the same sign continuation tolerance). In this example, the continuous number is 400. The alternating pattern generating unit 1214 may be configured to change the continuous number.

The alternating pattern generating unit 1214 outputs the generated alternating pattern signal to the second multiplexer unit 1215. In this example, the alternating pattern signal outputted from the alternating pattern generating unit 1214 is a parallel signal.

The second multiplexer unit 1215 multiplexes the encoded signal received from the encoding unit 1213 and the alternating pattern signal received from the alternating pattern generating unit 1214 to generate a transmission frame.

Based on the radio information received from the BB processing unit 11, the timing management unit 1211 controls the multiplexing of the encoded signal and the alternating pattern signal by the second multiplexer unit 1215. In other words, based on the radio information received from the BB processing unit 11, the timing management unit 1211 controls timings at which the encoded signal and the alternating pattern signal are outputted from the second multiplexer unit 1215.

In this example, the timing management unit 1211 specifies (or identifies) the DL communication periods and the DL non-communication periods based on the radio information received from the BB processing unit 11.

The timing management unit 1211 controls the second multiplexer unit 1215 such that the encoded signal is outputted in periods corresponding to the header sections within the specified DL communication and non-communication periods. The timing management unit 1211 controls the second multiplexer unit 1215 such that the encoded signal is outputted in a period corresponding to the payload section within the specified DL communication period. The timing management unit 1211 controls the second multiplexer unit 1215 such that the alternating pattern signal is outputted in the period corresponding to the payload section within the specified DL non-communication period.

The second multiplexer unit 1215 outputs the parallel signal representing the generated transmission frame to the serializer unit 122.

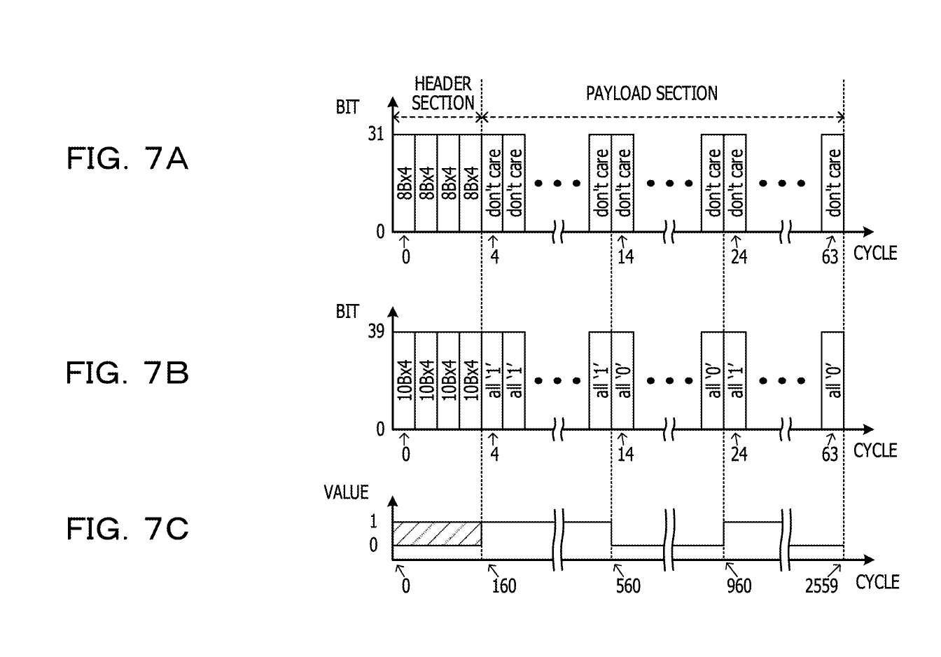

For example, as illustrated in FIG. 7A, in the DL non-communication period, no IQ data is stored in the payload section. In FIGS. 7A, 7B, and 7C, “don't care” represents an arbitrary value. For example, in the DL non-communication period, as the arbitrary value, a predetermined value (for example, 0 or 1) may be stored in the payload section.

For example, as illustrated in FIG. 7B, the second multiplexer unit 1215 outputs the alternating pattern signal in the period corresponding to the payload section within the DL non-communication period. In other words, in the DL non-communication period, the second multiplexer unit 1215 generates the transmission frame including the alternating pattern signal in its part correspond to the payload section.

In this example, the parallel signal outputted from the transmission frame processing unit 121 is 40 bits wide, and its transmission rate is 245.76 Mbps.

The parallel-serial converter unit 1221 converts the parallel signal received from the transmission frame processing unit 121 into a serial signal, and outputs the post-converted serial signal to the optical module 123. For example, as illustrated in FIG. 7C, the parallel-serial converter unit 1221 outputs the alternating pattern signal in the period corresponding to the payload section within the DL non-communication period.

The encoded signal outputted from the parallel-serial converter unit 1221 is an example of a first serial signal. The alternating pattern signal I outputted from the parallel-serial converter unit 1221 is an example of a second serial signal.

In this example, the transmission rate of the serial signal outputted from the serializer unit 122 is 9.8304 Gbps.

The optical module 123 converts the serial signal received from the serializer unit 122 into an optical signal. Thereafter, the optical module 123 transmits the post-converted optical signal to the RRH 20-m via the communication cable FC-m.

In this example, as illustrated in FIG. 3, an oscillator 13 generates a clock signal with a predetermined frequency, and outputs the generated clock signal to the serializer unit 122. The serializer unit 122 operates according to timing synchronized with the clock signal received from the oscillator 13. The serializer unit 122 outputs the clock signal received from the oscillator 13 to the transmission frame processing unit 121 and the BB processing unit 11. The transmission frame processing unit 121 and the BB processing unit 11 operate according to timing synchronized with the clock signal received from the serializer unit 122.

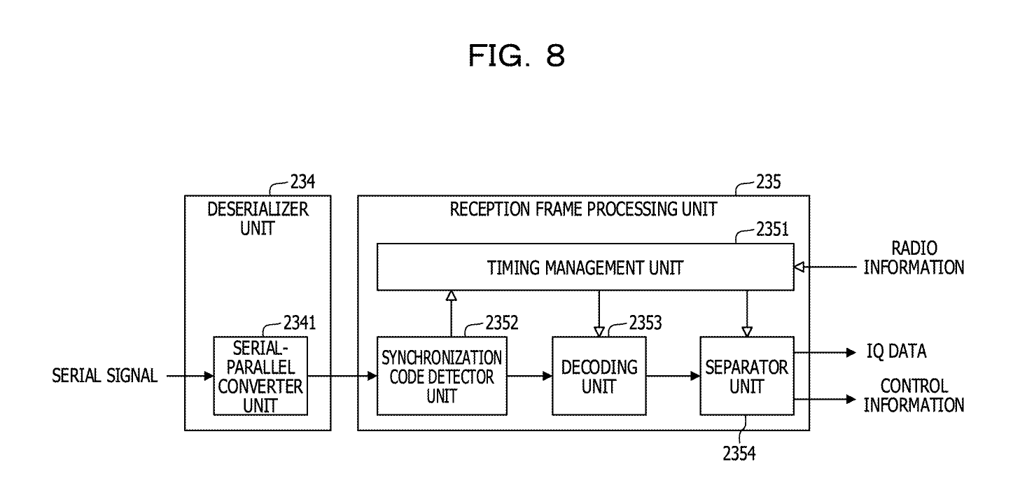

For example, as illustrated in FIG. 8, the deserializer unit 234 includes a serial-parallel converter unit 2341. The reception frame processing unit 235 includes a timing management unit 2351, a synchronization code detector unit 2352, a decoding unit 2353 and a separator unit 2354.

Via the communication cable FC-m, the optical module 233 receives the optical signal transmitted from the BBU 10. The optical module 233 converts the received optical signal into a serial signal. Thereafter, the optical module 233 outputs the post-converted serial signal to the deserializer unit 234.

The serial-parallel converter unit 2341 coverts the serial signal received from the optical module 233 into a parallel signal. Thereafter, the serial-parallel converter unit 2341 outputs the post-converted parallel signal to the reception frame processing unit 235.

The synchronization code detector unit 2352 detects a synchronization code from a bit string represented by the parallel signal received from the deserializer unit 234. The synchronization code is a predetermined bit string.

In this example, the synchronization code is stored in a predetermined part in the header section of the communication frame. Thus, by detecting the synchronization code, the synchronization code detector unit 2352 detects timing at which the synchronization code is detected (in other words, the position of the synchronization code in the bit string, or the phase of the communication frame). The synchronization code detector unit 2352 informs the timing management unit 2351 of the detection timing.

Based on the detected timing, the synchronization code detector unit 2352 performs word alignment on the parallel signal received from the deserializer unit 234. The word alignment is a process of controlling the phase of the parallel signal such that a bit at the beginning of the bit string (or the “word”) encoded according to the encoding method is transmitted through a predetermined one of multiple signal lines for transmitting the parallel signal.

The synchronization code detector unit 2352 outputs the word-aligned parallel signal to the decoding unit 2353.

The decoding unit 2353 decodes the bit string represented by the parallel signal received from the synchronization code detector unit 2352. The decoding unit 2353 performs the decoding according to a decoding method associated with the encoding method used by the encoding unit 1213. In this example, the decoding unit 2353 converts the bit string based on the relationships between the pre-converted bit strings and the post-converted bit strings which are determined in the encoding method used by the encoding unit 1213.

In a case where while the decoding unit 2353 is performing the decoding, the bit string of the decoding object is not matched with any one of the post-converted bit strings in the above-discussed relationships, the decoding unit 2353 detects the occurrence of abnormality in the decoding.

Based on the radio information received from the radio processing unit 22, the timing management unit 2351 controls the decoding by the decoding unit 2353.

In this example, the timing management unit 2351 controls the decoding unit 2353 to make the decoding unit 2353 perform the decoding in the periods corresponding to the header sections within the DL communication and non-communication periods. The timing management unit 2351 controls the decoding unit 2353 to make the decoding unit 2353 perform the decoding in the period corresponding to the payload section within the DL communication period. The timing management unit 2351 controls the decoding unit 2353 to make the decoding unit 2353 halt the decoding in the period corresponding to the payload section within the DL non-communication period.

While performing the decoding, the decoding unit 2353 outputs the post-decoded parallel signal to the separator unit 2354. While halting the decoding, the decoding unit 2353 outputs the parallel signal received from the synchronization code detector unit 2352 to the separator unit 2354.

The separator unit 2354 obtains (or extracts or separates) the IQ data and the control information from the data represented by the parallel signal received from the decoding unit 2353.

Based on the radio information received from the radio processing unit 22, the timing management unit 2351 controls the obtaining of the IQ data and the control information by the separator unit 2354. In other words, based on the radio information received from the radio processing unit 22, the timing management unit 2351 controls timings at which the separator unit 2354 obtains the IQ data and the control information.

The separator unit 2354 outputs the obtained IQ data to the radio processing unit 22.

In this example, as illustrated in FIG. 3, based in the serial signal received from the optical module 233, the deserializer unit 234 generates a clock signal. In this example, the deserializer unit 234 generates the clock signal based in a timing at which the value represented by the serial signal changes. The generation of the clock signal by the deserializer unit 234 may be referred to as a “clock data recovery.”

The deserializer unit 234 may be configured to include an oscillator, to control the phase of a clock signal generated by the oscillator based on the serial signal received from the optical module 233, and to thereby generate a clock signal synchronized with the serial signal.

The deserializer unit 234 outputs the generated clock signal to the reception frame processing unit 235, the radio processing unit 22, the transmission frame processing unit 231, and the serializer unit 232. The reception frame processing unit 235, the radio processing unit 22, the transmission frame processing unit 231, and the serializer unit 232 operate according to timing synchronized with the clock signal received from the deserializer unit 234.

The DL processing unit 301 is an example of the communication system for the downlink communication.

The transmission frame processing unit 121 and the serializer unit 122 are examples of the transmission circuit for the downlink communication. The encoding unit 1213 is an example of the encoding unit for the downlink communication. The serializer unit 122, the timing management unit 1211, and the second multiplexer unit 1215 are examples of the communication unit for the downlink communication.

The deserializer unit 234 and the reception frame processing unit 235 are examples of the reception circuit for the downlink communication. The deserializer unit 234 is an example of the reception unit for the downlink communication. The decoding unit 2353 and the timing management unit 2351 are examples of the decoding unit for the downlink communication.

Next, descriptions are provided for the UL processing unit 302. The UL processing unit 302 is configured in the same way as the DL processing unit 301, except that: the UL processing unit 302 processes the uplink signals instead of the downlink signals; and the I/F circuit 23 on the transmission side uses the clock signal generated by the deserializer unit 234.

The transmission frame processing unit 231 and the serializer unit 232 are configured in the same way as the transmission frame processing unit 121 and the serializer unit 122, respectively. The deserializer unit 124 and the reception frame processing unit 125 are configured in the same way as the deserializer unit 234 and the reception frame processing unit 235, respectively.

For example, as illustrated in FIG. 5, in the periods (in other words, the UL communication periods) T2, T4 in which the uplink communications are being performed, the UL processing unit 302 transmits a communication frame with the control information and the IQ data respectively stored in the header section and the payload section. Meanwhile, in the periods (in other words, the UL non-communication periods) T1, T3, T5 in which no uplink communications are performed, the UL processing unit 302 transmits a communication frame with the control information stored in the header section, and with no IQ data stored in the payload section.

In this example, the UL communication periods T2, T4 for the UL processing unit 302 are instances of a first period in which radio signals are communicated wirelessly. In this example, the UL non-communication periods T1, T3, T5 for the UL processing unit 302 are instances of a second period in which no radio signal is communicated wirelessly.

The UL processing unit 302 is an example of the communication system for the uplink communication.

The transmission frame processing unit 231 and the serializer unit 232 are examples of the transmission circuit for the uplink communication. The encoding unit in the transmission frame processing unit 231 is an example of the encoding unit for the uplink communication. The serializer unit 232, the timing management unit in the transmission frame processing unit 231, and the second multiplexer unit in the transmission frame processing unit 231 are examples of the communication unit for the uplink communication.

The deserializer unit 124 and the reception frame processing unit 125 are examples of the reception circuit for the uplink communication. The deserializer unit 124 is an example of the reception unit for the uplink communication. The decoding unit in the reception frame processing unit 125, and the timing management unit in the reception frame processing unit 125 are examples of the decoding unit for the uplink communication.

Next, referring to FIG. 5, descriptions are provided for an example of how the base station apparatus 1 operates.

First of all, descriptions are provided for how the base station apparatus 1 operates for the downlink communication in the period T1.

The BB processing unit 11 in the BBU 10 generates the IQ data. The I/F circuit 12-m generates the control information.

Thereafter, the transmission frame processing unit 121 in the I/F circuit 12-m encodes the IQ data generated by the BB processing unit 11. Furthermore, the transmission frame processing unit 121 encodes the control information generated by the I/F circuit 12-m.

Subsequently, the transmission frame processing unit 121 generates the transmission frame including the encoded code signal in the periods corresponding to the header section and the payload section. Furthermore, the serializer unit 122 in the I/F circuit 12-m converts the parallel signal representing the transmission frame generated by the transmission frame processing unit 121 into the serial signal.

After that, the optical module 123 in the I/F circuit 12-m converts the serial signal converted by the serializer unit 122 into the optical signal. Subsequently, the optical module 123 transmits the post-converted optical signal to the RRH 20-m via the communication cable FC-m.

Thereby, via the communication cable FC-m, the optical module 233 in the I/F circuit 23 receives the optical signal transmitted from the BBU 10. Thereafter, the optical module 233 converts the received optical signal into the serial signal.

Subsequently, the deserializer unit 234 in the I/F circuit 23 converts the serial signal converted by the optical module 233 into the parallel signal. Thereafter, in the periods corresponding to the header section and the payload section, the reception frame processing unit 235 in the I/F circuit 23 decodes the bit string represented by the parallel signal converted by the deserializer unit 234. Thereby, the reception frame processing unit 235 obtains the IQ data.

Via the antenna 21, the radio processing unit 22 in the RRH 20-m transmits the radio signal represented by the IQ data obtained by the reception frame processing unit 235.

Next, descriptions are provided for how the base station apparatus 1 operates for the uplink communication in the period T1.

In the period T1, the radio processing unit 22 in the RRH 20-m receives no radio signal. Accordingly, the radio processing unit 22 generates no IQ data. The I/F circuit 23 generates the control information. Thereafter, the transmission frame processing unit 231 in the I/F circuit 23 encodes the control information generated by the I/F circuit 23.

Subsequently, the transmission frame processing unit 231 generates the transmission frame including the encoded code signal in the period corresponding to the header section, and the alternating pattern signal in the period corresponding to the payload section. Thereafter, the serializer unit 232 in the I/F circuit 23 converts the parallel signal representing the transmission frame generated by the transmission frame processing unit 231 into the serial signal.

Thereafter, the optical module 233 in the I/F circuit 23 converts the serial signal converted by the serializer unit 232 into the optical signal. After that, the optical module 233 transmits the post-converted optical signal to the BBU 10 via the communication cable FC-m.

Thereby, via the communication cable FC-m, the optical module 123 in the I/F circuit 12-m receives the optical signal transmitted from the RRH 20-m. Thereafter, the optical module 123 converts the received optical signal into the serial signal.

Subsequently, the deserializer unit 124 in the I/F circuit 12-m converts the serial signal converted by the optical module 123 into the parallel signal. Thereafter, in the period corresponding to the header section, the reception frame processing unit 125 in the I/F circuit 12-m decodes the bit string represented by the parallel signal converted by the deserializer unit 124. Furthermore, in the period corresponding to the payload section, the reception frame processing unit 125 in the I/F circuit 12-m does not decode the bit string represented by the parallel signal converted by the deserializer unit 124.

Next, descriptions are provided for how the base station apparatus 1 operates for the downlink communication in the period T2.

In the period T2, the BB processing unit 11 in the BBU 10 generates no IQ data. The I/F circuit 12-m generates the control information. The transmission frame processing unit 121 in the I/F circuit 12-m encodes the control information generated by the I/F circuit 12-m.

Thereafter, the transmission frame processing unit 121 generates the transmission frame including the encoded code signal in the period corresponding to the header section, and the alternating pattern signal in the period corresponding to the payload section. After that, the serializer unit 122 in the I/F circuit 12-m converts the parallel signal representing the transmission frame generated by the transmission frame processing unit 121 into the serial signal.

Thereafter, the optical module 123 in the I/F circuit 12-m converts the serial signal converted by the serializer unit 122 into the optical signal. After that, the optical module 123 transmits the post-converted optical signal to the RRH 20-m via the communication cable FC-m.

Thereby, via the communication cable FC-m, the optical module 233 in the I/F circuit 23 receives the optical signal transmitted from the BBU 10. Thereafter, the optical module 233 converts the received optical signal into the serial signal.

Subsequently, the deserializer unit 234 in the I/F circuit 23 converts the serial signal converted by the optical module 233 into the parallel signal. Thereafter, in the period corresponding to the header section, the reception frame processing unit 235 in the I/F circuit 23 decodes the bit string represented by the parallel signal converted by the deserializer unit 234. Furthermore, in the period corresponding to the payload section, the reception frame processing unit 235 in the I/F circuit 23 does not decode the bit string represented by the parallel signal converted by the deserializer unit 234.

Next, descriptions are provided for how the base station apparatus 1 operates for the uplink communication in the period T2.

In the period T2, the radio processing unit 22 in the RRH 20-m receives the radio signal, and generates the IQ data representing the received radio signal. The I/F circuit 23 generates the control information. Subsequently, the transmission frame processing unit 231 in the I/F circuit 23 encodes the IQ data generated by the radio processing unit 22. The transmission frame processing unit 231 encodes the control information generated by the I/F circuit 23.

After that, the transmission frame processing unit 231 generates the transmission frame including the encoded code signal in the periods corresponding to the header section and the payload section. Furthermore, the serializer unit 232 in the I/F circuit 23 converts the parallel signal representing the transmission frame generated by the transmission frame processing unit 231 into the serial signal.

Subsequently, the optical module 233 in the I/F circuit 23 converts the serial signal converted by the serializer unit 232 into the optical signal. The optical module 233 transmits the post-converted optical signal to the BBU 10 via the communication cable FC-m.

Thereby, via the communication cable FC-m, the optical module 123 in the I/F circuit 12-m receives the optical signal transmitted from the RRH 20-m. Thereafter, the optical module 123 converts the received optical signal into the serial signal.

Subsequently, the deserializer unit 124 in the I/F circuit 12-m converts the serial signal converted by the optical module 123 into the parallel signal. Thereafter, in the periods corresponding to the header section and the payload section, the reception frame processing unit 125 in the I/F circuit 12-m decodes the bit string represented by the parallel signal converted by the deserializer unit 124. Thereby, the reception frame processing unit 125 obtains the IQ data. After that, the BB processing unit 11 in the BBU 10 processes the IQ data obtained by the reception frame processing unit 125.

The base station apparatus 1 operates in the period T3, T5 in the same way as in the period T1. Furthermore, the base station apparatus 1 operates in the period T4 in the same way as in the period T2.

As discussed above, in the first periods in which the downlink communication signals are communicated wirelessly, the I/F circuit 12-m of the first embodiment transmits the first serial signal representing the data encoded according to the encoding method. The encoding method is the method for converting an arbitrary bit string into a bit string which includes consecutive bits representing the same value where the number of such bits is equal to or less than a predetermined threshold value. Furthermore, in the second periods in which no downlink communication signals are communicated wirelessly, the I/F circuit 12-m transmits the second serial signal representing a bit string which includes consecutive bits representing the same value where the number of such bits is the continuous number greater than the threshold value.

Similarly, in the first periods in which the uplink communication signals are communicated wirelessly, the I/F circuit 23 of the first embodiment transmits the first serial signal representing the data encoded according to the encoding method. Furthermore, in the second periods in which no uplink communication signals are communicated wirelessly, the I/F circuit 23 transmits the second serial signal representing the bit string which includes the consecutive bits representing the same value where the number of such bits is the continuous number greater than the threshold value.

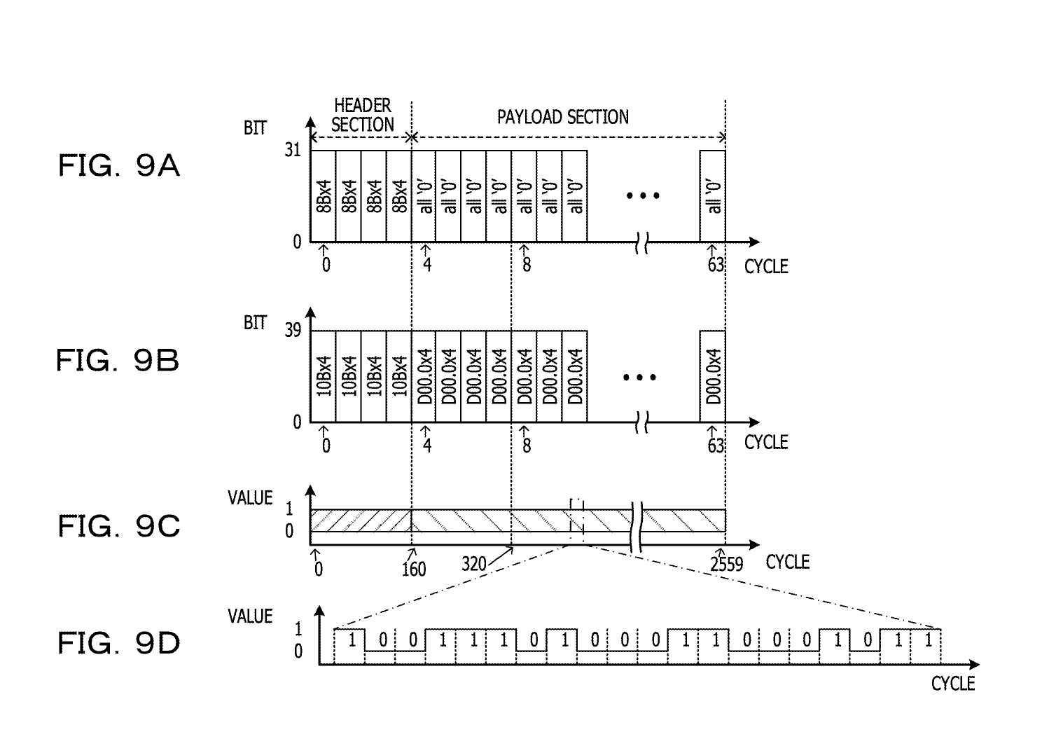

For example, as illustrated in FIG. 9A, in a second period in which no communication signal is communicated wirelessly, an I/F circuit of a comparative example generates a communication frame with predetermined values (0s in this example) stored (or padded) in the payload section. Thereafter, as illustrated in FIG. 9B, in the second period in which no communication signal is communicated wirelessly, the I/F circuit of the comparative example encodes the header section and the payload section which are included in the generated communication frame.

Furthermore, as illustrated in FIG. 9C, in the second period in which no communication signal is communicated wirelessly, the I/F circuit of the comparative example converts the encoded code signal into a serial signal. Thereafter, the I/F circuit converts the post-converted serial signal into an optical signal, and transmits the post-converted optical signal.

FIG. 9D illustrates an example of the serial signal in a period corresponding to the payload section within the second period in which no communication signal is communicated wirelessly. As illustrated in FIG. 9D, in the comparative example, in the period corresponding to the payload section within the second period in which no communication signal is communicated wirelessly, the number of consecutive bits representing the same value is equal to or less than the threshold value.

In contrast to this, in the first embodiment, in the period corresponding to the payload section within each second period in which no communication signal is communicated wirelessly, the number of consecutive bits representing the same value is the continuous number greater than the threshold value.

Accordingly, the I/F circuit 12-m and the I/F circuit 23 of the first embodiment are capable of reducing the toggle frequency in the second period. This makes it possible to reduce the amount of power consumption in the second period. For example, it is possible to reduce the amount of power consumption due to the switching operations of the I/F circuit 12-m and the I/F circuit 23 of the first embodiment to approximately 53% of the amount of power consumption due to the switching operation of the I/F circuit of the comparative example.

In the second period, too, the communication of the control information is maintained. This makes it possible to maintain the connection between the I/F circuit 12-m and the I/F circuit 23. It is accordingly possible to maintain the synchronization between the communication frames of the I/F circuit 12-m and the I/F circuit 23.

Furthermore, in the first embodiment, the second serial signal represents the bit string including the alternating series of the first bit string with the continuous number of 0s in succession and the second bit string with the continuous number of 1s in succession.

This makes it possible to reduce the toggle frequency in the second period. Accordingly, it is possible to reduce the amount of power consumption in the second period.

Furthermore, the I/F circuit 12-m and the I/F circuit 23 of the first embodiment are capable of specifying the second period based on the radio information.

In the case where the radio signals are communicated according to the TDD method, the periods in which no downlink radio signals are communicated wirelessly, and the periods in which no uplink radio signals are communicated wirelessly are provided.

The timing of the second period in the radio frame corresponds to the timing of the period in the radio frame in which the radio signals are communicated. The timing of the second period in the radio frame corresponds to the timing of the period in which the uplink communication is performed. The timing of the second period in the radio frame corresponds to the timing of the period in which the downlink communication is performed.

Thus, the I/F circuit 12-m and the I/F circuit 23 make it possible to detect the second period with high accuracy.

Moreover, in the first embodiment, the continuous number is less than the upper limit number. The upper limit number for the I/F circuit 23 is a number to be allowed for the I/F circuit 12-m to be synchronized with the I/F circuit 23 based in the received serial signal. The upper limit number for the I/F circuit 12-m is a number to be allowed for the I/F circuit 23 to be synchronized with the I/F circuit 12-m based in the received serial signal.

Thereby, the I/F circuit 23 is synchronized with the I/F circuit 12-m based on the serial signal received in the second period of the downlink. This makes it possible to maintain the synchronization between the I/F circuit 23 and the I/F circuit 12-m in the second period of the downlink as well. Similarly, the I/F circuit 12-m is synchronized with the I/F circuit 23 based on the serial signal received in the second period of the uplink. This makes it possible to maintain the synchronization between the I/F circuit 23 and the I/F circuit 12-m in the second period of the uplink as well.

Moreover, the I/F circuit 23 of the first embodiment decodes the data represented by the serial signal which is received in the first period in which the downlink radio signals are communicated wirelessly. In addition, the I/F circuit 23 does not decode the data represented by the serial signal which is received in the second period in which no downlink radio signals are communicated wirelessly.

Similarly, the I/F circuit 12-m of the first embodiment decodes the data represented by the serial signal which is received in the first period in which the uplink radio signals are communicated wirelessly. In addition, the I/F circuit 12-m does not decode the data represented by the serial signal which is received in the second period in which no uplink radio signals are communicated wirelessly.

This makes it possible to inhibit the occurrence of abnormality in the decoding. The abnormality in the decoding represents that the I/F circuit 12-m or the I/F circuit 23 fails to decode the data represented by the received serial signal.

### Second Embodiment

Next, descriptions are provided for a base station of a second embodiment. The base station of the second embodiment is different from the base statin of the first embodiment in that information on whether the payload section is made from the alternating pattern signal is stored in the header section. The following descriptions are provided focusing on what makes the base station of the second embodiment different from the base station of the first embodiment. Components of the second embodiment which are described using the same reference signs as those of the first embodiment are identical to or substantially the same as the components of the first embodiment.

The control information generated by the I/F circuit 12-m of the second embodiment includes flag information. The flag information indicates whether the payload section to be included in the communication frame together with the header section storing the flag information is formed from an unencoded alternating pattern signal.

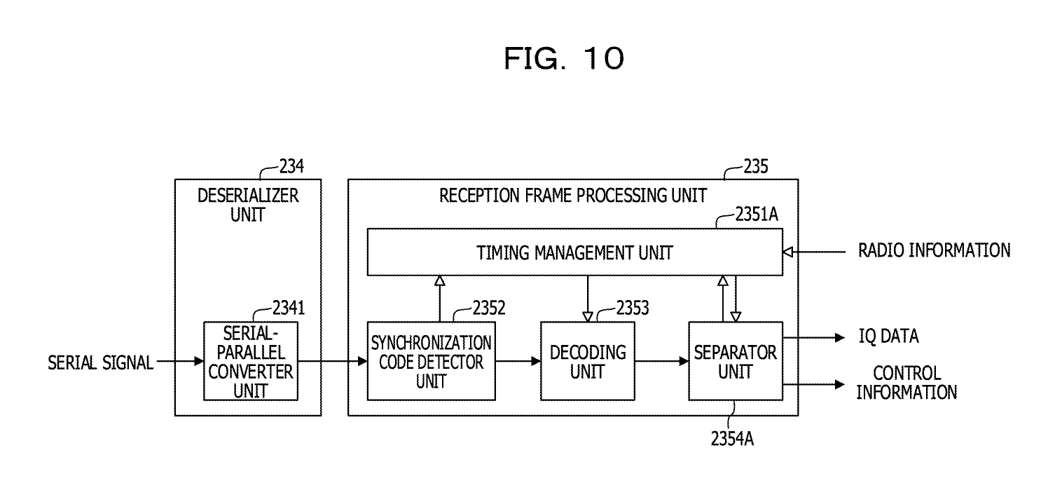

For example, as illustrated in FIG. 10, the reception frame processing unit 235 of the second embodiment includes a timing management unit 2351A and a separator unit 2354A instead of the timing management unit 2351 and the separator unit 2354 included in the reception frame processing unit 235 of the first embodiment.

The separator unit 2354A obtains (or extracts or separates) the IQ data and the control information from the data represented by the parallel signal received from the decoding unit 2353.

Based on the radio information received from the radio processing unit 22, the timing management unit 2351A controls the obtaining of the IQ data and the control information by the separator unit 2354A. In other words, based on the radio information received from the radio processing unit 22, the timing management unit 2351A controls timings at which the separator unit 2354A obtains the IQ data and the control information.

The separator unit 2354A outputs the obtained IQ data to the radio processing unit 22. In addition, the separator unit 2354A outputs the obtained control information to the timing management unit 2351A.

The timing management unit 2351A controls the decoding by the decoding unit 2353 based on the control information received from the separator unit 2354A instead of based on the radio information received from the radio processing unit 22.

In this example, in a case where the flag information included in the control information is information indicating the encoded state, the timing management unit 2351A controls the decoding unit 2353 to make the decoding unit 2353 perform the decoding in the period corresponding to the payload section to be included in the communication frame together with the header section storing the flag information. The information indicating the encoded state is the flag information indicating that the payload section to be included in the communication frame together with the header section storing the flag information is formed from the encoded code signal (in other words, is not formed from the alternating pattern signal).

In this example, in a case where the flag information included in the control information is information indicating the unencoded state, the timing management unit 2351A controls the decoding unit 2353 to make the decoding unit 2353 halt the decoding in the period corresponding to the payload section to be included in the communication frame together with the header section storing the flag information. The information indicating the unencoded state is the flag information indicating that the payload section to be included in the communication frame together with the header section storing the flag information is formed from the unencoded alternating pattern signal.

The separator unit and the timing management unit included in the reception frame processing unit 125 are configured in the same way as the separator unit 2354A and the timing management unit 2351A, respectively.

As discussed above, the base station apparatus 1 of the second embodiment provides the same working and effect as the base station apparatus 1 of the first embodiment.

In addition, the header section included in the communication frame of the second embodiment stores information on whether the payload section to be included in the communication frame together with the header is formed from the serial signal representing the unencoded data (in this example, the alternating pattern signal). Furthermore, the timing management unit 2351A specifies the second period based on the header section.

This makes it possible for the I/F circuit 12-m and the I/F circuit 23 to recognize whether the payload section included in the communication frame is formed from the serial signal representing the unencoded data. Accordingly, it is possible to inhibit the I/F circuit 12-m and the I/F circuit 23 from failing to decode the payload section (in other words, it is possible to inhibit the occurrence of abnormality in the decoding).

The I/F circuit 12-m and the I/F circuit 23 of the second embodiment are capable of inhibiting the occurrence of abnormality in the decoding based on factors not related to the radio information even in a case where no IQ data is stored in the payload section.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A communication method executed by a communication system including a transmission circuit and a reception circuit, the communication method comprising:
encoding, by the transmission circuit, inputted data according to an encoding method of converting a pre-converted bit string into a bit string in which a number of consecutive bits representing a same value is equal to or less than a predetermined threshold value,
transmitting a first serial signal representing the encoded data, in a first period in which a radio signal outputted from the transmission circuit is communicated wirelessly, and
transmitting a second serial signal representing a bit string which includes a continuous number of consecutive bits representing a same value, in a second period in which the radio signal is not communicated wirelessly, the continuous number being greater than the threshold value, and
receiving, by the reception circuit, the first serial signal and the second serial signal.

2. The communication method according to claim 1,
wherein the second serial signal represents a bit string including an alternating series of a first bit string including the continuous number of consecutive 0s and a second bit string including the continuous number of consecutive 1s.

3. The communication method according to claim 1, further comprising
specifying, by the transmission circuit, the second period based on at least one of information on whether to communicate the radio signal according to a time division duplex method, information on a timing of a period in which the radio signal is communicated in a radio frame used for wireless communication of the radio signal, information on a timing of a period in which an uplink communication is performed in the radio frame, and information on a timing of a period in which a downlink communication is performed in the radio frame.

4. The communication method according to claim 1,
wherein the continuous number is less than an upper limit number allowed for the reception circuit to be synchronized with the transmission circuit based on the first serial signal and the second serial signal.

5. The communication method according to claim 1, wherein
the first serial signal and the second serial signal each include a payload section and a header section, and
the header section indicates whether the payload section corresponding to the header section is formed from the second serial signal.

6. The communication method according to claim 5,
wherein the decoding includes specifying the second period based on the header section included in the second serial signal.

7. The communication method according to claim 1, further comprising
specifying, by the reception circuit, the second period based on at least one of information on whether to communicate the radio signal according to a time division duplex method, information on a timing of a period in which the radio signal is communicated in a radio frame used for wireless communication of the radio signal, information on a timing of a period in which an uplink communication is performed in the radio frame, and information on a timing of a period in which a downlink communication is performed in the radio frame.

8. The communication method according to claim 1,
wherein the encoding includes generating a first parallel signal representing a bit string which includes a continuous number of consecutive bits representing a same value, the continuous number being greater than the threshold value, and
wherein the communication method further comprising:
generating a second parallel signal representing a bit string which includes a continuous number of consecutive bits representing a same value, the continuous number being greater than the threshold value;
generating a transmission frame by multiplexing the first parallel signal and the second parallel signal; and
generating the first serial signal and the second serial signal by converting the transmission frame.

9. A communication system comprising:
a transmission circuit; and
a reception circuit,
wherein the transmission circuit is configured to:
encode inputted data according to an encoding method of converting a pre-converted bit string into a bit string in which the number of consecutive bits representing a same value is equal to or less than a predetermined threshold value,
transmit a first serial signal representing the encoded data, in a first period in which a radio signal outputted from the transmission circuit is communicated wirelessly, and
transmit a second serial signal representing a bit string which includes a continuous number of consecutive bits representing a same value, in a second period in which the radio signal is not communicated wirelessly, the continuous number being greater than the threshold value, and
wherein the reception circuit is configured to
receive the first serial signal and the second serial signal.

10. The communication system according to claim 9,
wherein the second serial signal represents a bit string including an alternating series of a first bit string including the continuous number of consecutive 0s and a second bit string including the continuous number of consecutive 1s.

11. The communication system according to claim 9,
wherein the transmission circuit is configured to specify the second period based on at least one of information on whether to communicate the radio signal according to a time division duplex method, information on a timing of a period in which the radio signal is communicated in a radio frame used for wireless communication of the radio signal, information on a timing of a period in which an uplink communication is performed in the radio frame, and information on a timing of a period in which a downlink communication is performed in the radio frame.

12. The communication system according to claim 9,
wherein the continuous number is less than an upper limit number allowed for the reception circuit to be synchronized with the transmission circuit based on the first serial signal and the second serial signal.

13. The communication system according to claim 9, wherein
the first serial signal and the second serial signal each include a payload section and a header section, and
the header section indicates whether the payload section corresponding to the header section is formed from the second serial signal.

14. The communication system according to claim 13,
wherein the reception circuit is configured to specify the second period based on the header section included in the second serial signal.
